(19) United States
(12) Patent Application Publication
(10) Pub. No.: US 2024/0337920 A1
(43) Pub. Date: Oct. 10, 2024

(54) DESIGN METHOD OF PHOTOMASK STRUCTURE

(71) Applicant: Powerchip Semiconductor Manufacturing Corporation, Hsinchu (TW)

(72) Inventors: Kuei Yu Chien, Miaoli County (TW); Yung Ching Mai, Taipei City (TW); Shin-Shing Yeh, Changhua County (TW); Chia-Chi Lin, Hsinchu County (TW); Jun-Cheng Lai, Hsinchu City (TW)

(73) Assignee: Powerchip Semiconductor Manufacturing Corporation, Hsinchu (TW)

(21) Appl. No.: 18/332,773

(22) Filed: Jun. 12, 2023

(30) Foreign Application Priority Data
Apr. 10, 2023 (TW) 112113343

(51) Int. Cl. G03F 1/36

(52) U.S. Cl. CPC G03F 1/36; G03F 1/26

(57) ABSTRACT

A design method of a photomask structure including the following steps is provided. A first layout pattern is provided. An assist pattern is added aside the first layout pattern. An optical proximity correction (OPC) is performed to convert the first layout pattern into a second layout pattern, wherein the assist pattern has an adjacent portion adjacent to the second layout pattern, a first distance between the adjacent portion and the second layout pattern is less than a safety distance, and the safety distance is a distance to prevent the assist pattern from being transferred to a photoresist layer during a lithography process. After the OPC is performed, the adjacent portion is shifted to increase the first distance to a second distance, wherein the second distance is greater than or equal to the safety distance.

### CROSS-REFERENCE TO RELATED APPLICATION

This application claims the priority benefit of Taiwan application serial no. 112113343, filed on Apr. 10, 2023. The entirety of the above-mentioned patent application is hereby incorporated by reference herein and made a part of this specification.

### BACKGROUND

### Technical Field

The invention relates to a design method of a photomask structure, and particularly relates to a design method of a photomask structure having assist pattern.

### Description of Related Art

In the current design method of the photomask structure, the assist pattern is added to improve the resolution. However, after performing the optical proximity correction (OPC) on the layout pattern, if the distance between the assist pattern and the layout pattern is too close, the assist pattern will be transferred to the photoresist layer during the lithography process, and the unexpected pattern is generated.

### SUMMARY

The invention provides a design method of a photomask structure, which can prevent the assist pattern from being transferred to the photoresist layer during the lithography process. The invention provides a design method of a photomask structure, which includes the following steps. A first layout pattern is provided. An assist pattern is added aside the first layout pattern. An optical proximity correction (OPC) is performed to convert the first layout pattern into a second layout pattern, wherein the assist pattern has an adjacent portion adjacent to the second layout pattern, a first distance between the adjacent portion and the second layout pattern is less than a safety distance, and the safety distance is a distance to prevent the assist pattern from being transferred to a photoresist layer during a lithography process. After the OPC is performed, the adjacent portion is shifted to increase the first distance to a second distance, wherein the second distance is greater than or equal to the safety distance.

According to an embodiment of the invention, in the design method of the photomask structure, the assist pattern is, for example, a sub-resolution assist feature (SRAF).

According to an embodiment of the invention, in the design method of the photomask structure, the safety distance may be greater than or equal to the minimum distance specified by the mask rule check (MRC).

According to an embodiment of the invention, in the design method of the photomask structure, an initial distance between the assist pattern and the first layout pattern may be less than the minimum distance specified by the mask rule check.

According to an embodiment of the invention, in the design method of the photomask structure, an initial distance between the assist pattern and the first layout pattern may be equal to the minimum distance specified by the mask rule check.

According to an embodiment of the invention, in the design method of the photomask structure, an initial distance between the assist pattern and the first layout pattern may be greater than the minimum distance specified by the mask rule check.

According to an embodiment of the invention, the design method of the photomask structure may further include the following step. A third layout pattern is provided. The assist pattern may be located between the first layout pattern and the third layout pattern.

According to an embodiment of the invention, in the design method of the photomask structure, the OPC may convert the third layout pattern into a fourth layout pattern.

According to an embodiment of the invention, in the design method of the photomask structure, a third distance between the assist pattern and the fourth layout pattern may be greater than or equal to the safety distance.

According to an embodiment of the invention, in the design method of the photomask structure, after the adjacent portion is shifted, a fourth distance between the adjacent portion and the fourth layout pattern may be greater than or equal to the safety distance.

According to an embodiment of the invention, in the design method of the photomask structure, the safety distance may be greater than or equal to the minimum distance specified by the mask rule check.

According to an embodiment of the invention, in the design method of the photomask structure, the photomask structure may be a binary mask or a phase shift mask (PSM).

Based on the above description, in the design method of the photomask structure according to the invention, the assist pattern is added aside the first layout pattern. The OPC is performed to convert the first layout pattern into the second layout pattern. The assist pattern has the adjacent portion adjacent to the second layout pattern. The first distance between the adjacent portion and the second layout pattern is less than the safety distance. The safety distance is the distance to prevent the assist pattern from being transferred to the photoresist layer during the lithography process. After the OPC is performed, the adjacent portion is shifted to increase the first distance to the second distance. The second distance is greater than or equal to the safety distance. In this way, when the lithography process is performed by using the photomask structure designed by the design method of the photomask structure according to the invention, the assist pattern can be prevented from being transferred to the photoresist layer, thereby preventing the generation of the unexpected pattern. In addition, the design method of the photomask structure according to the invention can have a larger process margin and can improve the process resolution. Furthermore, after the lithography process is performed by using the photomask structure designed by the design method of the photomask structure according to the invention, the critical dimension of the obtained photoresist pattern can reach the target.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart illustrating a design method of a photomask structure according to some embodiments of the invention.

FIG. 2A to FIG. 2D are top views illustrating a design process of a photomask structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

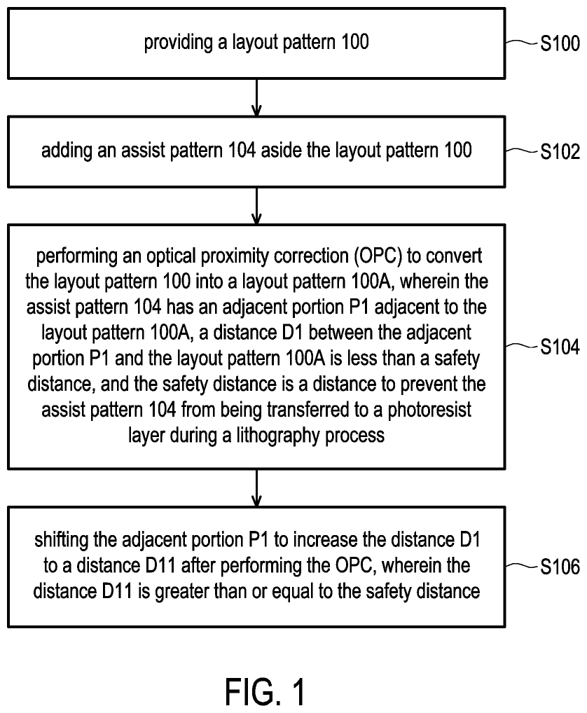

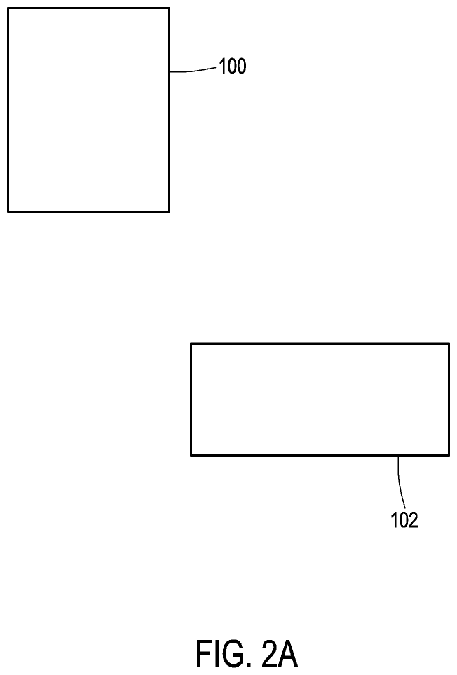

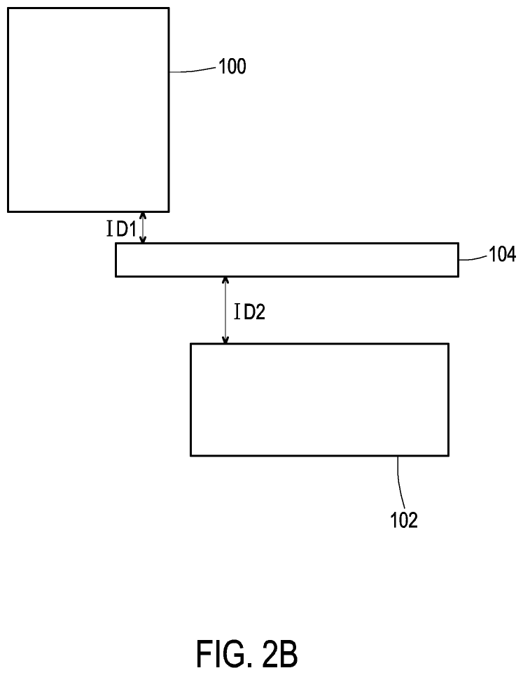

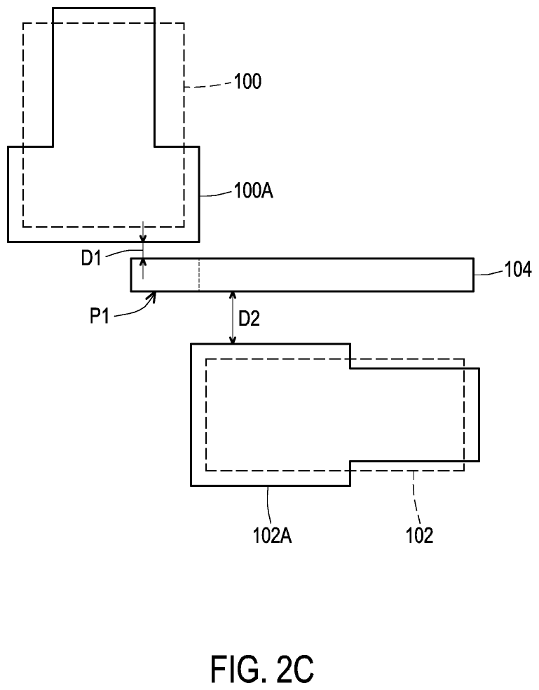

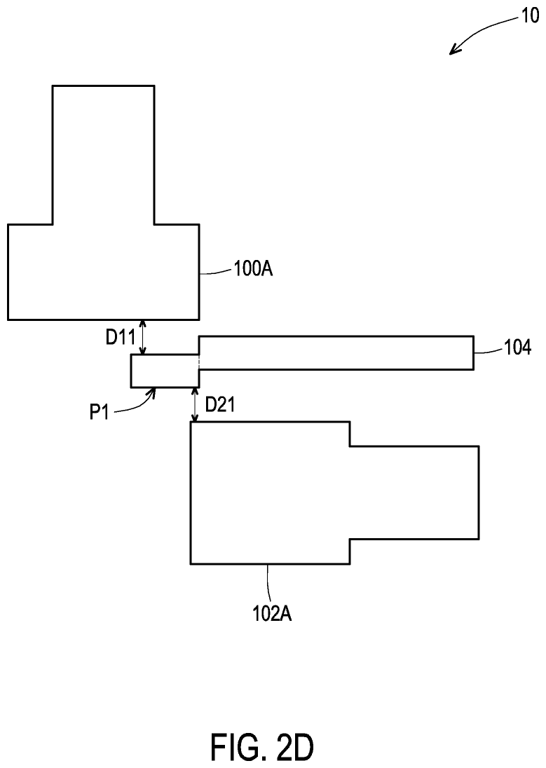

FIG. 1 is a flow chart illustrating a design method of a photomask structure according to some embodiments of the invention. FIG. 2A to FIG. 2D are top views illustrating a design process of a photomask structure according to some embodiments of the invention.

Referring to FIG. 1 and FIG. 2A, in a step S100, a layout pattern 100 is provided. In some embodiments, in the step S100, a layout pattern 102 may be further provided. In some embodiments, the layout pattern 100 and the layout pattern 102 may be separated from each other.

Referring to FIG. 1 and FIG. 2B, in a step S102, an assist pattern 104 is added aside the layout pattern 100. In some embodiments, an initial distance ID1 between the assist pattern 104 and the layout pattern 100 may be less than, equal to, or greater than the minimum distance specified by the mask rule check. In some embodiments, the assist pattern 104 may be located between the layout pattern 100 and the layout pattern 102. In some embodiments, an initial distance ID2 between the assist pattern 104 and the layout pattern 102 may be greater than the initial distance ID1 between the assist pattern 104 and the layout pattern 100. In some embodiments, the assist pattern 104 is, for example, a sub-resolution assist feature (SRAF).

Referring to FIG. 1 and FIG. 2C, in a step S104, an optical proximity correction (OPC) is performed to convert the layout pattern 100 into a layout pattern 100A, wherein the assist pattern 104 has an adjacent portion P1 adjacent to the layout pattern 100A, a distance D1 between the adjacent portion P1 and the layout pattern 100A is less than a safety distance, and the safety distance is a distance to prevent the assist pattern 104 from being transferred to a photoresist layer during a lithography process. In the present embodiment, the safety distance may be greater than or equal to the minimum distance specified by the mask rule check. In addition, in the step S104, the OPC may convert the layout pattern 102 into a layout pattern 102A. In some embodiments, a distance D2 between the assist pattern 104 and the layout pattern 102A may be greater than or equal to the safety distance.

Referring to FIG. 1 and FIG. 2D, in a step S106, after the OPC is performed, the adjacent portion P1 is shifted to increase the distance D1 to a distance D11, wherein the distance D11 is greater than or equal to the safety distance. In this way, when the lithography process is performed by using the photomask structure 10 designed by the above-mentioned design method of the photomask structure, the assist pattern 104 can be prevented from being transferred to the photoresist layer, thereby preventing the generation of the unexpected pattern. In some embodiments, after the adjacent portion P1 is shifted, a distance D21 between the adjacent portion P1 and the layout pattern 102A may be greater than or equal to the safety distance.

In some embodiments, the layout pattern 100A and the layout pattern 102A may be main patterns on the photomask structure 10. In some embodiments, the photomask structure 10 may be a binary mask or a phase shift mask. In some embodiments, the photomask structure 10 may be a binary mask, and the layout pattern 100A, the layout pattern 102A, and the assist pattern 104 may be opaque patterns (e.g., opaque regions) on the binary mask, but the invention is not limited thereto. In some embodiments, the photomask structure 10 may be a binary mask, and the layout pattern 100A, the layout pattern 102A, and the assist pattern 104 may be light-transmitting patterns (e.g., light-transmitting regions) on the binary mask. In some embodiments, the photomask structure 10 may be a phase shift mask, and the layout pattern 100A, the layout pattern 102A, and the assist pattern 104 may be phase shift patterns on the phase shift mask, but the invention is not limited thereto. In some embodiments, the photomask structure 10 may be a phase shift mask, and the layout pattern 100A, the layout pattern 102A, and the assist pattern 104 may be light-transmitting patterns (e.g., light-transmitting regions) on the phase shift mask.

Based on the above embodiments, in the above-mentioned design method of the photomask structure, the assist pattern 104 is added aside the layout pattern 100. The OPC is performed to convert the layout pattern 100 into the layout pattern 100A. The assist pattern 104 has the adjacent portion P1 adjacent to the layout pattern 100A. The distance D1 between the adjacent portion P1 and the layout pattern 100A is less than the safety distance. The safety distance is the distance to prevent the assist pattern 104 from being transferred to the photoresist layer during the lithography process. After the OPC is performed, the adjacent portion P1 is shifted to increase the distance D1 to the distance D11. The distance D11 is greater than or equal to the safety distance. In this way, when the lithography process is performed by using the photomask structure 10 designed by the above-mentioned design method of the photomask structure, the assist pattern 104 can be prevented from being transferred to the photoresist layer, thereby preventing the generation of the unexpected pattern. In addition, the above-mentioned design method of the photomask structure can have a larger process margin and can improve the process resolution. Furthermore, after the lithography process is performed by using the photomask structure 10 designed by the above-mentioned design method of the photomask structure, the critical dimension of the obtained photoresist pattern can reach the target.

In summary, in the design method of the photomask structure of the aforementioned embodiments, an assist pattern is added aside a first layout pattern. An OPC is performed to convert the first layout pattern into a second layout pattern. The assist pattern has an adjacent portion adjacent to the second layout pattern. A first distance between the adjacent portion and the second layout pattern is less than a safety distance. The safety distance is a distance to prevent the assist pattern from being transferred to a photoresist layer during a lithography process. After the OPC is performed, the adjacent portion is shifted to increase the first distance to a second distance. The second distance is greater than or equal to the safety distance. In this way, when the lithography process is performed by using the photomask structure designed by the design method of the photomask structure of the aforementioned embodiments, the assist pattern can be prevented from being transferred to the photoresist layer, thereby preventing the generation of the unexpected pattern. In addition, the design method of the photomask structure of the aforementioned embodiments can have a larger process margin and can improve the process resolution. Furthermore, after the lithography process is performed by using the photomask structure designed by the design method of the photomask structure of the aforementioned embodiments, the critical dimension of the obtained photoresist pattern can reach the target.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A design method of a photomask structure, comprising:
providing a first layout pattern;
adding an assist pattern aside the first layout pattern;
performing an optical proximity correction (OPC) to convert the first layout pattern into a second layout pattern, wherein the assist pattern has an adjacent portion adjacent to the second layout pattern, a first distance between the adjacent portion and the second layout pattern is less than a safety distance, and the safety distance is a distance to prevent the assist pattern from being transferred to a photoresist layer during a lithography process; and
shifting the adjacent portion to increase the first distance to a second distance after performing the OPC, wherein the second distance is greater than or equal to the safety distance.

2. The design method of the photomask structure according to claim 1, wherein the assist pattern comprises a sub-resolution assist feature.

3. The design method of the photomask structure according to claim 1, wherein the safety distance is greater than or equal to a minimum distance specified by a mask rule check.

4. The design method of the photomask structure according to claim 1, wherein an initial distance between the assist pattern and the first layout pattern is less than a minimum distance specified by a mask rule check.

5. The design method of the photomask structure according to claim 1, wherein an initial distance between the assist pattern and the first layout pattern is equal to a minimum distance specified by a mask rule check.

6. The design method of the photomask structure according to claim 1, wherein an initial distance between the assist pattern and the first layout pattern is greater than a minimum distance specified by a mask rule check.

7. The design method of the photomask structure according to claim 1, further comprising:
providing a third layout pattern, wherein the assist pattern is located between the first layout pattern and the third layout pattern.

8. The design method of the photomask structure according to claim 7, wherein the OPC converts the third layout pattern into a fourth layout pattern.

9. The design method of the photomask structure according to claim 8, wherein a third distance between the assist pattern and the fourth layout pattern is greater than or equal to the safety distance.

10. The design method of the photomask structure according to claim 9, wherein after the adjacent portion is shifted, a fourth distance between the adjacent portion and the fourth layout pattern is greater than or equal to the safe distance.

11. The design method of the photomask structure according to claim 10, wherein the safety distance is greater than or equal to a minimum distance specified by a mask rule check.

12. The design method of the photomask structure according to claim 1, wherein the photomask structure comprises a binary mask or a phase shift mask.
